(19) United States
(12) Patent Application Publication
(10) Pub. No.: US 2026/0313796 A1
(43) Pub. Date: Oct. 8, 2026

(54) METHOD FOR MANUFACTURING CIRCUIT BOARD AND CIRCUIT BOARD

(71) Applicant: Resonac Corporation, Tokyo (JP)

(72) Inventor: Hirokazu NOMA, Tokyo (JP)

(21) Appl. No.: 19/479,966

(22) PCT Filed: Oct. 3, 2023
(86) PCT No.: PCT/JP2023/036102

§ 371 Date: Oct. 29, 2025

(51) Int. Cl. H05K 1/11; H05K 1/02; H05K 1/03; H05K 3/46

(52) U.S. Cl. CPC H05K 1/115; H05K 1/0274; H05K 1/0306; H05K 3/4644; H05K 2203/107

(57) ABSTRACT

In a method for manufacturing a circuit board, a glass laminate is prepared, the glass laminate including a first outer glass layer including a first surface, and a first inner glass layer bonded to the first outer glass layer on a side opposite to the first surface. A first hole is formed that penetrates at least the first outer glass layer and the first inner glass layer from the first surface toward a second surface by irradiating the first surface with a laser light. A light absorptance of the first inner glass layer is lower than a light absorptance of the first outer glass layer. This makes it possible to easily form a hole for providing a connection member that electrically connects a first terminal formed on the first surface and a second terminal formed on the second surface.

### TECHNICAL FIELD

The present disclosure relates to a method for manufacturing a circuit board and a circuit board.

### BACKGROUND ART

Flip-chip mounting is known as a method for mounting an integrated circuit formed on a silicon wafer. In recent years, in this flip-chip mounting, from the viewpoint of suppressing warpage of a package substrate, adoption of a glass laminate as a substrate serving as a core of the package substrate has been considered.

When performing flip-chip mounting, it is necessary to bond a surface opposite to a mounting surface of the package substrate to, for example, a motherboard in order to efficiently draw out terminals. In this case, a through-hole penetrating from the mounting surface to an opposite surface of the package substrate is formed, and a connection member for electrically connecting terminals formed on the mounting surface and the opposite surface, respectively, needs to be provided.

When the above-described glass laminate is adopted as a base material serving as the core of the package substrate, a through-hole for providing the connection member is formed in the glass laminate by irradiating the glass laminate with a laser light. Non Patent Literature 1 discloses an example of a method for forming a through-hole in a glass laminate by irradiation with a laser light.

### CITATION LIST

### Non Patent Literature

Non Patent Literature 1: K. Demir et al., “First demonstration of copper-plated through-package-via (TPV) reliability in ultra-thin 3D glass interposers with double-side component assembly,” 2015 IEEE 65th Electronic Components and Technology Conference (ECTC), pp. 666-671, 2015.

### SUMMARY OF INVENTION

### Technical Problem

When forming the above-described through-hole in a glass laminate by irradiation with a laser light, a surface of the glass laminate is irradiated with the laser light to form a hole that penetrates the glass layers constituting the glass laminate. At this time, it is necessary to allow vaporized components, which are vaporized by the laser light irradiation, to escape to the outside of the hole. Therefore, a conceivable method is to secure time for the vaporized components to move out of the hole by sequentially removing the glass layers constituting the glass laminate one by one while changing an irradiation position of the laser light. However, this method has a problem in that it is necessary to perform alignment each time the irradiation position of the laser light is changed, which requires a long time for the laser light irradiation. Therefore, there is a need for a method for manufacturing a circuit board that can easily form a hole for providing a connection member in a circuit board including a glass laminate as a substrate.

### Solution to Problem

The present disclosure is required to provide a method for manufacturing a circuit board that can easily form a hole for providing a connection member for a circuit board including a glass laminate as a substrate.

### Advantageous Effects of Invention

[1] The present disclosure, as one aspect, relates to a method for manufacturing a circuit board, the circuit board comprising: a substrate including a first surface and a second surface located on a side opposite to the first surface; a first terminal formed on the first surface; and a second terminal formed on the second surface and electrically connected to the first terminal. In this method for manufacturing a circuit board, the method comprises: preparing a glass laminate as the substrate, wherein the glass laminate, in which a plurality of glass layers are laminated, includes the first surface and the second surface; and irradiating the glass laminate with a laser light, wherein, in the preparing, the glass laminate is prepared in which the plurality of glass layers include a first outer glass layer including the first surface, and a first inner glass layer bonded to the first outer glass layer on a side opposite to the first surface, wherein, in the irradiating, a first hole is formed that penetrates at least the first outer glass layer and the first inner glass layer from the first surface toward the second surface by irradiating the first surface with the laser light, and wherein, a light absorptance of the first inner glass layer is lower than a light absorptance of the first outer glass layer.

In this manufacturing method, the light absorptance of the first inner glass layer is lower than the light absorptance of the first outer glass layer. That is, in the irradiating, a time required for the laser light to penetrate the first inner glass layer is longer than a time required for the laser light to penetrate the first outer glass layer. On the other hand, compared to a time required for the alignment of the irradiation position of the laser light described above, the time required for the laser light to penetrate the first inner glass layer is short. Therefore, by making the light absorptance of the first inner glass layer lower than the light absorptance of the first outer glass layer, it is possible to shorten a time required for the laser light irradiation while allowing the vaporized component to escape to the outside of the first hole while the laser light penetrates the first inner glass layer in the process of forming the first hole. From the above, according to the method for manufacturing a circuit board described in [1], it is possible to easily form a hole for providing a connection member.

[2] In the method for manufacturing a circuit board described in [1], in the preparing, a glass laminate may be prepared in which the first inner glass layer includes the second surface. In the irradiating, the first hole may be formed that penetrates from the first surface to the second surface. In this case, even if the glass laminate has a two-layer structure including the first outer glass layer and the first inner glass layer, it is possible to shorten the time required for the laser light irradiation while allowing the vaporized component to escape to the outside of the first hole while the laser light penetrates the first inner glass layer in the process of forming the first hole. Therefore, according to the method for manufacturing a circuit board described in [2], even if the glass laminate has the two-layer structure including the first outer glass layer and the first inner glass layer, the hole for providing a connection member can be easily formed.

[3] In the method for manufacturing a circuit board described in [1], in the preparing, the glass laminate may be prepared in which the plurality of glass layers further include a second outer glass layer including the second surface. In the irradiating, a second hole may be further formed that penetrates at least the second outer glass layer from the second surface toward the first surface and communicates with the first hole. In this case, even if the glass laminate has a structure of three or more layers including at least the first outer glass layer, the first inner glass layer, and the second outer glass layer, it is possible to shorten the time required for the laser light irradiation while allowing the vaporized component to escape to the outside of the first hole while the laser light penetrates the first inner glass layer in the process of forming the first hole. Therefore, according to the method for manufacturing a circuit board described in [3], even if the glass laminate has the structure of three or more layers including at least the first outer glass layer, the first inner glass layer, and the second outer glass layer, the hole for providing a connection member can be easily formed.

[4] In the method for manufacturing a circuit board described in [3], in the preparing, the glass laminate may be prepared in which the plurality of glass layers further include a second inner glass layer bonded to the second outer glass layer on a side opposite to the second surface. In the irradiating, the second hole may be formed that penetrates the second outer glass layer and the second inner glass layer by irradiating the second surface with the laser light. A light absorptance of the second inner glass layer may be lower than the light absorptance of the second outer glass layer. In this case, by making the light absorptance of the second inner glass layer lower than the light absorptance of the second outer glass layer, it is possible to shorten a time required for the laser light irradiation while allowing the vaporized component to escape to the outside of the second hole while the laser light penetrates the second inner glass layer also in the process of forming the second hole. Therefore, according to the method for manufacturing a circuit board described in [4], the hole for providing the connection member can be formed even more easily.

[5] In the method for manufacturing a circuit board described in [4], the light absorptance of the second inner glass layer may be lower than the light absorptance of the first outer glass layer.

[6] In the method for manufacturing a circuit board described in [4] or [5], in the preparing, the glass laminate may be prepared which further includes a plurality of third inner glass layers located between the first inner glass layer and the second inner glass layer. In the irradiating, the first hole may be formed that penetrates the first outer glass layer, the first inner glass layer, and at least one third inner glass layer of the plurality of third inner glass layers, and the second hole may be formed that penetrates the second outer glass layer, the second inner glass layer, and a remaining third inner glass layer of the plurality of third inner glass layers. A light absorptance of the plurality of third inner glass layers may be lower than the light absorptance of the first outer glass layer and the light absorptance of the second outer glass layer. In this case, by making the light absorptance of the plurality of third inner glass layers lower than the light absorptance of the first outer glass layer and the light absorptance of the second outer glass layer, it is possible to shorten the time required for the laser light irradiation while allowing the vaporized components generated by the laser light to escape to the outside of the first hole and the second hole in both the process of forming the first hole and the process of forming the second hole. Therefore, according to the method for manufacturing a circuit board described in [6], the hole for providing the connection member can be easily formed.

[7] In the method for manufacturing a circuit board according to any one of [1] to [6], each of the plurality of glass layers may be a glass plate. According to the method for manufacturing a circuit board described in [7], the glass laminate in which the plurality of glass layers are laminated can be easily prepared.

[8] In the method for manufacturing a circuit board according to any one of [1] to [7], each of the plurality of glass layers may be bonded via an adhesive. In this case, even if a defect or the like exists in any of the plurality of glass layers, since each of the plurality of glass layers is bonded via the adhesive, it is difficult for the defect to affect the other glass layers. Therefore, according to the method for manufacturing a circuit board described in [8], a mechanical strength of the glass laminate can be improved.

[9] The present disclosure, as another aspect, relates to a circuit board. This circuit board comprises: a glass laminate including a first surface and a second surface located on a side opposite to the first surface, in which a plurality of glass layers are laminated; a first terminal formed on the first surface; and a second terminal formed on the second surface and electrically connected to the first terminal. The plurality of glass layers include a first outer glass layer including the first surface, and a first inner glass layer bonded to the first outer glass layer on a side opposite to the first surface. A through-hole penetrating from the first surface toward the second surface is formed in the glass laminate. A light absorptance of the first inner glass layer is lower than a light absorptance of the first outer glass layer.

[10] In the circuit board described in [9], the first inner glass layer may include the second surface.

[11] In the circuit board described in [9], the plurality of glass layers may further include a second outer glass layer including the second surface. The light absorptance of the first inner glass layer may be lower than a light absorptance of the second outer glass layer.

[12] In the circuit board described in [11], the plurality of glass layers may further include a second inner glass layer bonded to the second outer glass layer on a side opposite to the second surface. A light absorptance of the second inner glass layer may be lower than the light absorptance of the second outer glass layer.

[13] In the circuit board described in [12], the light absorptance of the second inner glass layer may be lower than the light absorptance of the first outer glass layer.

[14] In the circuit board described in [12] or [13], the plurality of glass layers may further include a plurality of third inner glass layers located between the first inner glass layer and the second inner glass layer. A light absorptance of the plurality of third inner glass layers may be lower than the light absorptance of the first outer glass layer and the light absorptance of the second outer glass layer.

[15] In the circuit board according to any one of [9] to [14], each of the plurality of glass layers may be a glass plate.

[16] In the circuit board according to any one of [9] to [15], each of the plurality of glass layers may be bonded via an adhesive.

### BRIEF DESCRIPTION OF DRAWINGS

FIG. 1 is a diagram showing an example of a circuit board according to a first embodiment of the present disclosure.

FIG. 2(a) to (d) of FIG. 2 are cross-sectional views for explaining a method for manufacturing the circuit board shown in FIG. 1.

FIG. 3(a) to (d) of FIG. 3 are cross-sectional views for explaining the method for manufacturing the circuit board shown in FIG. 1, showing steps performed after the steps shown in FIG. 2.

FIG. 4 is a diagram showing an example of a circuit board according to a second embodiment of the present disclosure.

FIG. 5(a) to (d) of FIG. 5 are cross-sectional views for explaining a method for manufacturing the circuit board shown in FIG. 4.

FIG. 6(a) to (d) of FIG. 6 are cross-sectional views for explaining the method for manufacturing the circuit board shown in FIG. 4, showing steps performed after the steps shown in FIG. 5.

FIG. 7 is a diagram showing an example of a circuit board according to a third embodiment of the present disclosure.

FIG. 8(a) to (e) of FIG. 8 are cross-sectional views for explaining a method for manufacturing the circuit board shown in FIG. 7.

### DESCRIPTION OF EMBODIMENTS

Hereinafter, some embodiments of the present disclosure will be described in detail with reference to the drawings as necessary. In the following description, the same or corresponding parts are denoted by the same reference numerals, and redundant description will be omitted. In addition, positional relationships such as up, down, left, and right are based on the positional relationships shown in the drawings, unless otherwise specified. When terms such as “left,” “right,” “front,” “back,” “top,” “bottom,” “upper,” and “lower” are used in this specification and the claims, these are intended for explanation and do not necessarily mean that they are permanently in this relative position. Furthermore, the dimensional ratios in the drawings are not limited to the illustrated ratios. In this specification, the term “step” is included in this term not only as an independent step but also when the intended action of the step is achieved even if it cannot be clearly distinguished from other steps.

### First Embodiment

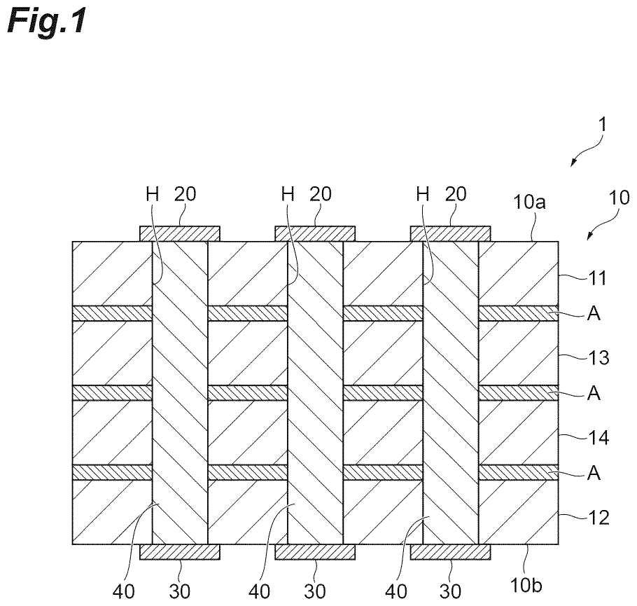

A circuit board and a method for manufacturing the circuit board according to a first embodiment of the present disclosure will be described with reference to FIGS. 1 to 3.

### (Configuration of Circuit Board)

First, the configuration of the circuit board according to the first embodiment will be described with reference to FIG. 1. FIG. 1 shows an example of the circuit board according to the first embodiment. As shown in FIG. 1, a circuit board 1 is, for example, a substrate serving as a core of a package substrate, and includes a glass laminate 10, a first terminal 20, a second terminal 30, and a connection member 40. In the circuit board 1, the glass laminate 10 functions as a substrate and includes a first surface 10a and a second surface 10b located on a side opposite to the first surface 10a.

The glass laminate 10 is configured by laminating a plurality of glass layers, and in the present embodiment, is configured by laminating four glass layers. As shown in FIG. 1, the glass laminate 10 includes, as the four glass layers, a first outer glass layer 11, a second outer glass layer 12, a first inner glass layer 13, and a second inner glass layer 14. In the present embodiment, each of the first outer glass layer 11, the second outer glass layer 12, the first inner glass layer 13, and the second inner glass layer 14 is a glass plate.

In the glass laminate 10, the first outer glass layer 11 and the second outer glass layer 12 constitute the outermost layers. Therefore, in the present embodiment, the first outer glass layer 11 includes the first surface 10a as its surface, and the second outer glass layer 12 includes the second surface 10b as its surface.

In the glass laminate 10, the first inner glass layer 13 is bonded to the first outer glass layer 11 on a side opposite to the first surface 10a, and the second inner glass layer 14 is bonded to the second outer glass layer 12 on a side opposite to the second surface 10b. Furthermore, the first inner glass layer 13 and the second inner glass layer 14 are bonded to each other. Therefore, in the glass laminate 10, the first outer glass layer 11, the first inner glass layer 13, the second inner glass layer 14, and the second outer glass layer 12 are laminated in this order. In the present embodiment, each of the first outer glass layer 11, the second outer glass layer 12, the first inner glass layer 13, and the second inner glass layer 14 is bonded via an adhesive A.

In the glass laminate 10, the light absorptance of the first outer glass layer 11 and the light absorptance of the first inner glass layer 13 are different from each other, and the light absorptance of the second outer glass layer 12 and the light absorptance of the second inner glass layer 14 are different from each other. Specifically, the light absorptance of the first inner glass layer 13 is lower than the light absorptance of the first outer glass layer 11, and the light absorptance of the second inner glass layer 14 is lower than the light absorptance of the second outer glass layer 12. The light absorptance of the second inner glass layer 14 may be lower than the light absorptance of the first outer glass layer 11. Here, the light absorptance is a ratio indicating the degree to which a glass layer absorbs light when light is incident on the glass layer; the higher the light absorptance, the more easily the incident light is absorbed, and the lower the light absorptance, the less easily the incident light is absorbed. The light absorptance may be expressed using, for example, an absorption coefficient.

The light absorptance of the first outer glass layer 11 is, for example, 0.5 cm⁻¹ or more and 3.5 cm⁻¹ or less, and the light absorptance of the first inner glass layer 13 is, for example, 0.1 cm⁻¹ or more and 1.0 cm⁻¹ or less. The light absorptance of the second outer glass layer 12 is, for example, 0.5 cm⁻¹ or more and 3.5 cm⁻¹ or less, and the light absorptance of the second inner glass layer 14 is, for example, 0.1 cm⁻¹ or more and 1.0 cm⁻¹ or less.

As shown in FIG. 1, the first terminal 20 is formed on the first surface 10a, and the second terminal 30 is formed on the second surface 10b. The first terminal 20 and the second terminal 30 are electrically connected to each other. In the present embodiment, a through-hole H penetrating from the first surface 10a toward the second surface 10b is formed in the glass laminate 10, and the first terminal 20 and the second terminal 30 are electrically connected to each other via the connection member 40 disposed in the through-hole H. The connection member 40 may be, for example, a wiring or a conductive via.

### (Method for Manufacturing Circuit Board)

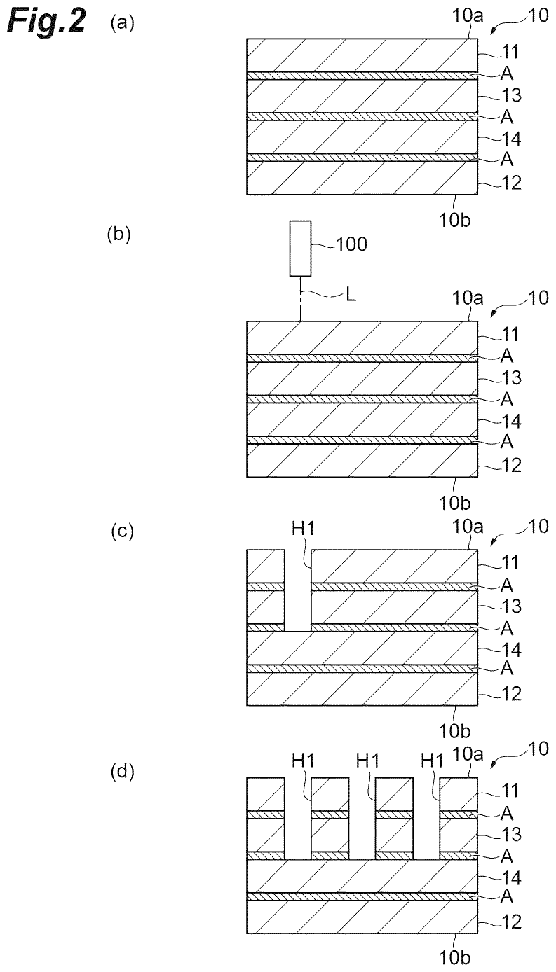

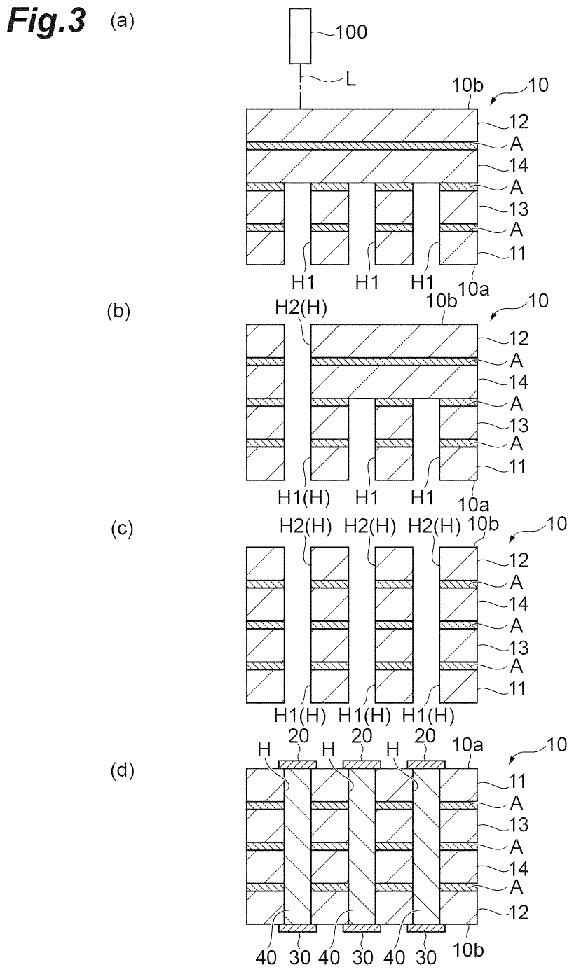

Next, a method for manufacturing the circuit board 1 will be described with reference to FIGS. 2 and 3. (a) to (d) of FIG. 2 are cross-sectional views for explaining the method for manufacturing the circuit board shown in FIG. 1. (a) to (d) of FIG. 3 are cross-sectional views for explaining the method for manufacturing the circuit board shown in FIG. 1, showing steps performed after the steps shown in FIG. 2.

The circuit board 1 can be manufactured, for example, through the following steps (a) to (c). That is, the method for manufacturing the circuit board 1 includes the following steps (a) to (c).
a) A step of preparing, as a substrate, a glass laminate including a first surface and a second surface, in which a plurality of glass layers are laminated, wherein the plurality of glass layers include a first outer glass layer including the first surface, a second outer glass layer including the second surface, a first inner glass layer bonded to the first outer glass layer on a side opposite to the first surface, and a second inner glass layer bonded to the second outer glass layer on a side opposite to the second surface.
b) A step of irradiating the glass laminate with a laser light.
c) A step of forming a connection member, a first terminal, and a second terminal.

Further, the step b) of irradiating the glass laminate with a laser light includes the following steps.
b1) A step of forming a first hole that penetrates the first outer glass layer and the first inner glass layer from the first surface toward the second surface by irradiating the first surface with a laser light.
b2) A step of repeating the above b1).
b3) A step of forming a second hole that penetrates the second outer glass layer and the second inner glass layer from the second surface toward the first surface and communicates with the first hole by irradiating the second surface with a laser light.
b4) A step of repeating the above b3).
   [Step (a)]

Step (a) is a step of preparing the glass laminate 10. In step (a) in the present embodiment, the glass laminate 10 including the first surface 10a and the second surface 10b, in which a plurality of glass layers are laminated, is prepared. The glass laminate 10 is, for example, a glass substrate. In this case, the glass laminate 10 may be a glass substrate having a thickness of, for example, 0.05 mm or more and 1.65 mm or less.

As shown in (a) of FIG. 2, the glass laminate 10 prepared in step (a) of the present embodiment includes, as the plurality of glass layers, a first outer glass layer 11, a second outer glass layer 12, a first inner glass layer 13, and a second inner glass layer 14. In the glass laminate 10 prepared in step (a), each of the first outer glass layer 11, the second outer glass layer 12, the first inner glass layer 13, and the second inner glass layer 14 is a glass plate. Each of the first outer glass layer 11, the second outer glass layer 12, the first inner glass layer 13, and the second inner glass layer 14 is made of glass such as alkali silicate glass, alkali-free glass, or quartz glass.

In the glass laminate 10, the first outer glass layer 11 and the second outer glass layer 12 constitute the outermost layers. Therefore, in the glass laminate 10 prepared in step (a), the first outer glass layer 11 includes the first surface 10a as its surface, and the second outer glass layer 12 includes the second surface 10b as its surface.

In the glass laminate 10 prepared in step (a), the first inner glass layer 13 is bonded to the first outer glass layer 11 on a side opposite to the first surface 10a, and the second inner glass layer 14 is bonded to the second outer glass layer 12 on a side opposite to the second surface 10b. Furthermore, the first inner glass layer 13 and the second inner glass layer 14 are bonded to each other. Therefore, in the glass laminate 10 prepared in step (a), the first outer glass layer 11, the first inner glass layer 13, the second inner glass layer 14, and the second outer glass layer 12 are laminated in this order. Each of the first outer glass layer 11, the second outer glass layer 12, the first inner glass layer 13, and the second inner glass layer 14 is bonded via an adhesive A.

In the glass laminate 10 prepared in step (a), the light absorptance of the first outer glass layer 11 and the light absorptance of the first inner glass layer 13 are different from each other, and the light absorptance of the second outer glass layer 12 and the light absorptance of the second inner glass layer 14 are different from each other. Specifically, the light absorptance of the first inner glass layer 13 is lower than the light absorptance of the first outer glass layer 11, and the light absorptance of the second inner glass layer 14 is lower than the light absorptance of the second outer glass layer 12. In the glass laminate 10 prepared in step (a), the light absorptance of the second inner glass layer 14 may be lower than the light absorptance of the first outer glass layer 11.

In the glass laminate 10 prepared in step (a), the light absorptance of the first outer glass layer 11 is, for example, 0.5 cm⁻¹ or more and 3.5 cm⁻¹ or less, and the light absorptance of the first inner glass layer 13 is, for example, 0.1 cm⁻¹ or more and 1.0 cm⁻¹ or less. In the glass laminate 10 prepared in step (a), the light absorptance of the second outer glass layer 12 is, for example, 0.5 cm⁻¹ or more and 3.5 cm⁻¹ or less, and the light absorptance of the second inner glass layer 14 is, for example, 0.1 cm⁻¹ or more and 1.0 cm-1 or less.

In order to realize such a configuration in which the light absorptance of the first outer glass layer 11 and the light absorptance of the first inner glass layer 13 are different from each other, for example, the color of the first outer glass layer 11 and the color of the first inner glass layer 13 may be made different from each other. Similarly, in order to realize a configuration in which the light absorptance of the second outer glass layer 12 and the light absorptance of the second inner glass layer 14 are different from each other, for example, the color of the second outer glass layer 12 and the color of the second inner glass layer 14 may be made different from each other.

In the glass laminate 10 prepared in step (a), the thickness of the first outer glass layer 11, the thickness of the second outer glass layer 12, the thickness of the first inner glass layer 13, and the thickness of the second inner glass layer 14 may be the same or different from each other. The thickness of the first outer glass layer 11, the thickness of the second outer glass layer 12, the thickness of the first inner glass layer 13, and the thickness of the second inner glass layer 14 is, for example, 0.035 mm or more and 0.7 mm or less, preferably 0.05 mm or more and 0.5 mm or less, and more preferably 0.1 mm or more and 0.3 mm or less.

[Step (b)]

Step (b) is a step of irradiating the glass laminate 10 with a laser light. In step (b), first, the first surface 10a of the glass laminate 10 is irradiated with a laser light. In step (b) in the present embodiment, as shown in (b) of FIG. 2, a laser irradiation apparatus 100 is used to irradiate the first surface 10a with a laser light L. In this case, the laser irradiation apparatus 100 recognizes a positioning mark provided in advance on the first surface 10a and irradiates the positioning mark with the laser light L. In the present embodiment, a plurality of the positioning marks are provided on the first surface 10a. The positioning mark is provided, for example, by performing etching or laser processing on the first surface 10a.

As the laser irradiation apparatus 100, a known laser irradiation apparatus can be used, such as an Nd:YAG (Neodymium-doped Yttrium Aluminum Garnet) laser, a laser ranging from the near-infrared region to the visible region and further to the ultraviolet region by combining an Nd:YAG laser and wavelength conversion, or an excimer laser such as a KrF excimer laser with a wavelength of 248 nm, an ArF excimer laser with a wavelength of 193 nm, or an F₂ excimer laser with a wavelength of 157 nm. From the viewpoint of processability, it is preferable to use an Nd:YAG laser as the laser irradiation apparatus 100. When an Nd:YAG laser is used as the laser irradiation apparatus 100, a laser of the third harmonic (wavelength 355 nm) is used. Further, when an Nd:YAG laser is used as the laser irradiation apparatus 100, the pulse width of the Nd:YAG laser is set to, for example, 100 fs or more and 1 ns or less.

In step (b) in the present embodiment, by the irradiation of the first surface 10a with the laser light L as described above, a first hole H1 that penetrates the first outer glass layer 11 and the first inner glass layer 13 from the first surface 10a toward the second surface 10b is formed in the glass laminate 10, as shown in (c) of FIG. 2. That is, in step (b) in the present embodiment, the first hole H1 is formed by irradiating the first surface 10a with the laser light L. The first hole H1 formed by the above method has a diameter of, for example, 0.02 mm or more and 0.15 mm or less.

Subsequently, the formation of the first hole H1 by the irradiation with the laser light L described above is repeated. As a result, as shown in (d) of FIG. 2, a plurality of first holes H1 are formed in the glass laminate 10. The pitch of the plurality of first holes H1 is, for example, 0.04 mm or more and 1.0 mm or less. In the example shown in (d) of FIG. 2, three first holes H1 are formed in the glass laminate 10.

Subsequently, the glass laminate 10 is turned upside down, and the second surface 10b of the glass laminate 10 is irradiated with a laser light. In step (b) in the present embodiment, as shown in (a) of FIG. 3, the laser irradiation apparatus 100 is used to irradiate the second surface 10b with the laser light L. In this case, similarly to the irradiation of the first surface 10a with the laser light L, the laser irradiation apparatus 100 recognizes a positioning mark provided in advance on the second surface 10b and irradiates the positioning mark with the laser light L. Here, the positioning mark provided on the second surface 10b is provided at a position corresponding to the positioning mark provided on the first surface 10a.

In step (b) in the present embodiment, by the irradiation of the second surface 10b with the laser light L as described above, a second hole H2 that penetrates the second outer glass layer 12 and the second inner glass layer 14 from the second surface 10b toward the first surface 10a is formed in the glass laminate 10. That is, in step (b) in the present embodiment, the second hole H2 is formed by irradiating the second surface 10b with the laser light L. The diameter of the second hole H2 formed by the irradiation of the second surface 10b with the laser light L is the same as the diameter of the first hole H1.

As described above, the positioning mark provided on the second surface 10b is provided at a position corresponding to the positioning mark provided on the first surface 10a. Therefore, the second hole H2 and the first hole H1 formed in step (b) communicate with each other, and thereby, a through-hole H penetrating from the first surface 10a toward the second surface 10b is formed in the glass laminate 10. In step (b) in the present embodiment, a through-hole H is formed that penetrates the first outer glass layer 11, the first inner glass layer 13, the second inner glass layer 14, and the second outer glass layer 12 from the first surface 10a toward the second surface 10b.

Subsequently, the formation of the second hole H2 by the irradiation with the laser light L described above is repeated. As a result, as shown in (c) of FIG. 3, a plurality of second holes H2 are formed in the glass laminate 10, and a plurality of through-holes H are formed. The pitch of the plurality of second holes H2 is, for example, the same as the pitch of the plurality of first holes H1. That is, the pitch of the plurality of through-holes H in the present embodiment is, for example, the same as the pitch of the plurality of first holes H1. In the example shown in (c) of FIG. 3, three through-holes H are formed in the glass laminate 10.

[Step (c)]

Step (c) is a step of forming the first terminal 20, the second terminal 30, and the connection member 40 in the glass laminate 10. In step (c) in the present embodiment, first, a conductive material is filled into the through-hole H to form a conductive via as the connection member 40. In this case, the connection member 40 is formed by filling a conductive paste as a conductive material into the through-hole H. The conductive paste is configured to include, for example, copper or the like.

Subsequently, the first terminal 20 is formed on the first surface 10a, and the second terminal 30 is formed on the second surface 10b so as to be electrically connected to the first terminal 20. In step (c) in the present embodiment, the second terminal 30 is formed on the second surface 10b so as to be electrically connected to the first terminal 20 via the connection member 40. In this manner, as shown in (d) of FIG. 3, the first terminal 20 and the second terminal 30, which are electrically connected to each other by the connection member 40, are formed.

Through the above steps, the circuit board 1 shown in FIG. 1 is manufactured.

As described above, in the method for manufacturing the circuit board 1 according to the present embodiment, the light absorptance of the first inner glass layer 13 is lower than the light absorptance of the first outer glass layer 11. That is, in step (b), the time required for the laser light L to penetrate the first inner glass layer 13 is longer than the time required for the laser light L to penetrate the first outer glass layer 11. On the other hand, compared to the time required for the alignment of the irradiation position of the laser light L, the time required for the laser light L to penetrate the first inner glass layer 13 is short. Therefore, by making the light absorptance of the first inner glass layer 13 lower than the light absorptance of the first outer glass layer 11, it is possible to shorten the time required for the laser light L irradiation step while allowing the vaporized component to escape to the outside of the hole while the laser light L penetrates the first inner glass layer 13 in the process of forming the first hole H1. From the above, according to the method for manufacturing the circuit board 1, the through-hole H for providing the connection member 40 can be easily formed.

In the method for manufacturing the circuit board 1, even in a glass laminate having a structure of three or more layers like the glass laminate 10, it is possible to shorten the time required for the laser light L irradiation step while allowing the vaporized component to escape to the outside of the first hole H1 while the laser light L penetrates the first inner glass layer 13 in the process of forming the first hole H1. Therefore, according to the method for manufacturing the circuit board 1, even if the glass laminate has a structure of three or more layers, the through-hole H for providing the connection member 40 can be easily formed.

In the method for manufacturing the circuit board 1, the light absorptance of the second inner glass layer 14 is lower than the light absorptance of the second outer glass layer 12. In this case, also in the process of forming the second hole H2, it is possible to shorten the time required for the laser light L irradiation step while allowing the vaporized component to escape to the outside of the second hole H2 while the laser light L penetrates the second inner glass layer 14. Therefore, according to the method for manufacturing the circuit board 1, the through-hole H for providing the connection member 40 can be formed even more easily.

In the method for manufacturing the circuit board 1, each of the first outer glass layer 11, the second outer glass layer 12, the first inner glass layer 13, and the second inner glass layer 14 is a glass plate. Therefore, according to the method for manufacturing the circuit board 1, the glass laminate 10 in which a plurality of glass layers are laminated can be easily prepared in step (a)

In the method for manufacturing the circuit board 1, each of the first outer glass layer 11, the second outer glass layer 12, the first inner glass layer 13, and the second inner glass layer 14 is bonded via the adhesive A. In this case, even if a defect or the like exists in any of the first outer glass layer 11, the second outer glass layer 12, the first inner glass layer 13, and the second inner glass layer 14, since each glass layer is bonded via the adhesive A, it is difficult for the defect to affect the other glass layers. Therefore, according to the method for manufacturing the circuit board 1, the mechanical strength of the glass laminate 10 can be improved.

### Second Embodiment

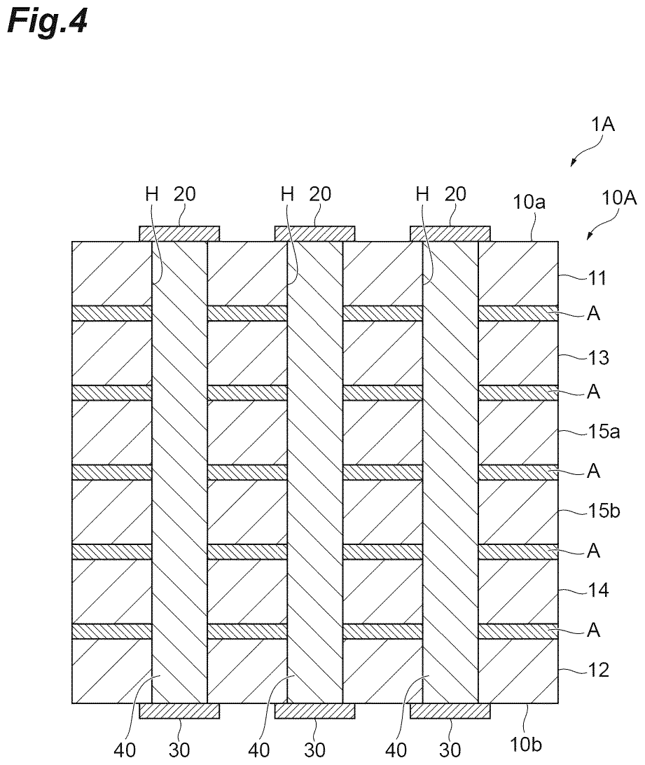

Next, a circuit board and a method for manufacturing the circuit board according to a second embodiment of the present disclosure will be described with reference to FIGS. 4 to 6. Hereinafter, points different from the first embodiment will be mainly described, and descriptions similar to or overlapping with the first embodiment may be omitted.

### (Configuration of Circuit Board)

First, the configuration of a circuit board 1A according to the second embodiment will be described with reference to FIG. 4. FIG. 4 is a diagram showing an example of a circuit board according to the second embodiment of the present disclosure. As shown in FIG. 4, the circuit board 1A is, for example, a substrate serving as a core of a package substrate, and includes a glass laminate 10A, the first terminal 20, the second terminal 30, and the connection member 40. The glass laminate 10A, similarly to the glass laminate 10, includes the first surface 10a and the second surface 10b.

The glass laminate 10A, similarly to the glass laminate 10, is configured by laminating a plurality of glass layers, and in the present embodiment, is configured by laminating six glass layers. As shown in FIG. 4, the glass laminate 10A includes, as the six glass layers, the first outer glass layer 11, the second outer glass layer 12, the first inner glass layer 13, the second inner glass layer 14, and a plurality of third inner glass layers 15a, 15b. Also in the present embodiment, each of the first outer glass layer 11, the second outer glass layer 12, the first inner glass layer 13, the second inner glass layer 14, and the plurality of third inner glass layers 15a, 15b is a glass plate.

In the glass laminate 10A, the first outer glass layer 11 and the second outer glass layer 12 constitute the outermost layers. Therefore, also in the present embodiment, the first outer glass layer 11 includes the first surface 10a as its surface, and the second outer glass layer 12 includes the second surface 10b as its surface.

In the glass laminate 10A, the plurality of third inner glass layers 15a, 15b are located between the first inner glass layer 13 and the second inner glass layer 14. Specifically, the third inner glass layer 15a is bonded to the first inner glass layer 13 on a side opposite to the first surface 10a, and the third inner glass layer 15b is bonded to the second inner glass layer 14 on a side opposite to the second surface 10b. Furthermore, the third inner glass layer 15a and the third inner glass layer 15b are bonded to each other. Therefore, in the glass laminate 10A, the first outer glass layer 11, the first inner glass layer 13, the third inner glass layer 15a, the third inner glass layer 15b, the second inner glass layer 14, and the second outer glass layer 12 are laminated in this order. Also in the present embodiment, each of the first outer glass layer 11, the second outer glass layer 12, the first inner glass layer 13, the second inner glass layer 14, and the plurality of third inner glass layers 15a, 15b is bonded via the adhesive A.

In the glass laminate 10A, the light absorptance of the third inner glass layers 15a, 15b and the light absorptance of the first outer glass layer 11 and the light absorptance of the second outer glass layer 12 are different from each other. Specifically, the light absorptance of the third inner glass layers 15a, 15b is lower than the light absorptance of the first outer glass layer 11 and the light absorptance of the second outer glass layer 12.

The light absorptance of the plurality of third inner glass layers 15a, 15b is, for example, 0.1 cm⁻¹ or more and 1.0 cm⁻¹ or less. The light absorptance of the third inner glass layer 15a and the light absorptance of the third inner glass layer 15b may be the same or different from each other.

Since the configuration of the first terminal 20, the second terminal 30, and the connection member 40 in the glass laminate 10A is the same as the configuration of the first terminal 20, the second terminal 30, and the connection member 40 in the glass laminate 10, a detailed description thereof is omitted.

### (Method for Manufacturing Circuit Board)

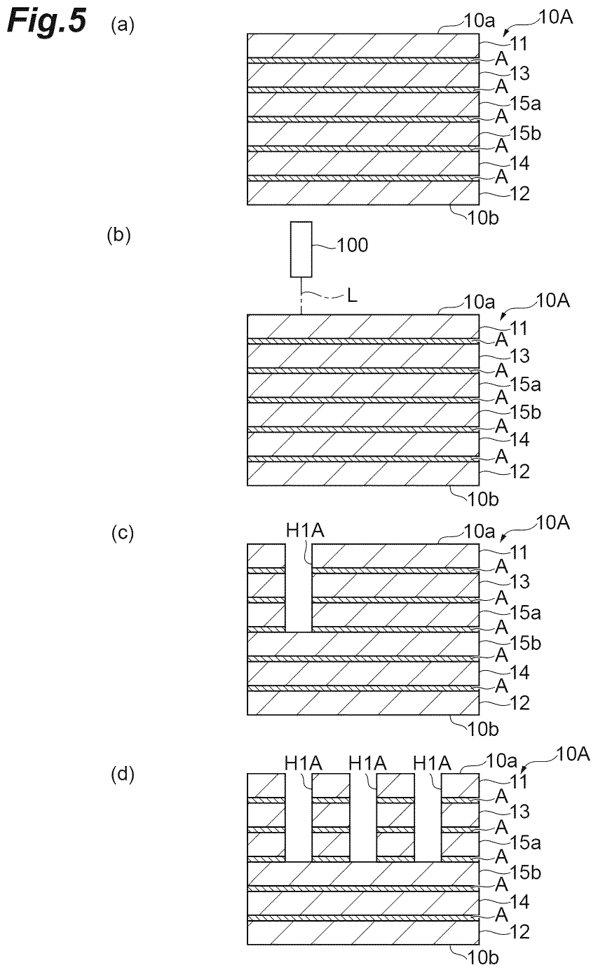

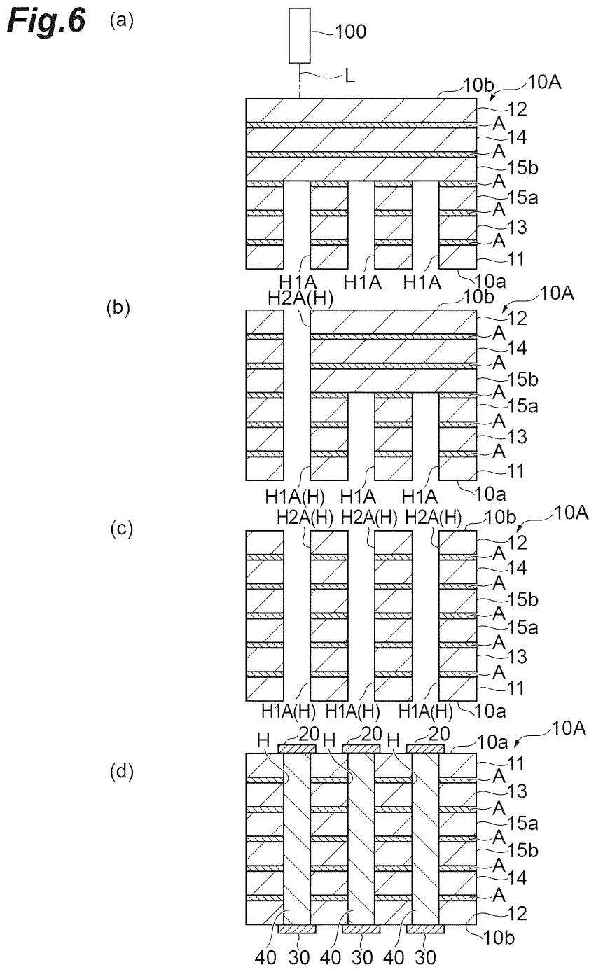

Next, a method for manufacturing the circuit board 1A will be described with reference to FIGS. 5 and 6. FIG. 5 is a cross-sectional view for explaining the method for manufacturing the circuit board shown in FIG. 4. FIG. 6 is a cross-sectional view for explaining the method for manufacturing the circuit board shown in FIG. 4, showing steps after the steps shown in FIG. 5.

The circuit board 1A can be manufactured, for example, through the following steps (d) to (f). That is, the method for manufacturing the circuit board 1A includes the following steps (d) to (f).
d) A step of preparing, as a substrate, a glass laminate including a first surface and a second surface, in which a plurality of glass layers are laminated, wherein the plurality of glass layers include a first outer glass layer including the first surface, a second outer glass layer including the second surface, a first inner glass layer bonded to the first outer glass layer on a side opposite to the first surface, a second inner glass layer bonded to the second outer glass layer on a side opposite to the second surface, and a plurality of third inner glass layers located between the first inner glass layer and the second inner glass layer.
e) A step of irradiating the glass laminate with a laser light.
f) A step of forming a connection member, a first terminal, and a second terminal.

Further, the step e) of irradiating the glass laminate with a laser light includes the following steps.
e1) A step of forming a first hole that penetrates the first outer glass layer, the first inner glass layer, and at least one third inner glass layer of the plurality of third inner glass layers from the first surface toward the second surface by irradiating the first surface with a laser light.
e2) A step of repeating the above e1).
e3) A step of forming a second hole that penetrates the second outer glass layer, the second inner glass layer, and a remaining third inner glass layer of the plurality of third inner glass layers from the second surface toward the first surface and communicates with the first hole by irradiating the second surface with a laser light.
e4) A step of repeating the above e3).
   [Step (d)]

Step (d) is a step of preparing the glass laminate 10A. In step (d) in the present embodiment, the glass laminate 10A including the first surface 10a and the second surface 10b, in which a plurality of glass layers are laminated, is prepared. The glass laminate 10A is, for example, a glass substrate. In this case, the glass laminate 10A may be a glass substrate having a thickness of, for example, 0.05 mm or more and 1.65 mm or less.

As shown in (a) of FIG. 5, the glass laminate 10A prepared in step (d) of the present embodiment includes, as the plurality of glass layers, the first outer glass layer 11, the second outer glass layer 12, the first inner glass layer 13, the second inner glass layer 14, and the plurality of third inner glass layers 15a, 15b. Each of the plurality of third inner glass layers 15a, 15b is also made of glass such as alkali silicate glass, alkali-free glass, or quartz glass.

Also in the glass laminate 10A, the first outer glass layer 11 and the second outer glass layer 12 constitute the outermost layers. Therefore, also in the glass laminate 10A prepared in step (d), the first outer glass layer 11 includes the first surface 10a as its surface, and the second outer glass layer 12 includes the second surface 10b as its surface.

In the glass laminate 10A prepared in step (d), the plurality of third inner glass layers 15a, 15b are located between the first inner glass layer 13 and the second inner glass layer 14. Specifically, the third inner glass layer 15a is bonded to the first inner glass layer 13 on a side opposite to the first surface 10a, and the third inner glass layer 15b is bonded to the second inner glass layer 14 on a side opposite to the second surface 10b. Furthermore, the third inner glass layer 15a and the third inner glass layer 15b are bonded to each other. Therefore, in the glass laminate 10A prepared in step (d), the first outer glass layer 11, the first inner glass layer 13, the third inner glass layer 15a, the third inner glass layer 15b, the second inner glass layer 14, and the second outer glass layer 12 are laminated in this order. Each of the first outer glass layer 11, the second outer glass layer 12, the first inner glass layer 13, the second inner glass layer 14, and the plurality of third inner glass layers 15a, 15b is bonded via the adhesive A.

In the glass laminate 10A prepared in step (d), the light absorptance of the third inner glass layers 15a, 15b and the light absorptance of the first outer glass layer 11 and the light absorptance of the second outer glass layer 12 are different from each other. Specifically, the light absorptance of the third inner glass layers 15a, 15b is lower than the light absorptance of the first outer glass layer 11 and the light absorptance of the second outer glass layer 12. Since the relationship between the light absorptance of the first outer glass layer 11 and the light absorptance of the first inner glass layer 13, and the relationship between the light absorptance of the second outer glass layer 12 and the light absorptance of the second inner glass layer 14 are the same as the relationships in the glass laminate 10, a detailed description thereof is omitted.

In the glass laminate 10A prepared in step (d), the light absorptance of the third inner glass layers 15a, 15b is, for example, 0.1 cm⁻¹ or more and 1.0 cm⁻¹ or less. Since the ranges of the light absorptance of the first outer glass layer 11, the light absorptance of the second outer glass layer 12, the light absorptance of the first inner glass layer 13, and the light absorptance of the second inner glass layer 14 in the glass laminate 10A are the same as the ranges in the glass laminate 10, a detailed description thereof is omitted.

In order to realize such a configuration in which the light absorptance of the first outer glass layer 11 and the light absorptance of the second outer glass layer 12 and the light absorptance of the plurality of third inner glass layers 15a, 15b are different from each other, for example, the color of the first outer glass layer 11 and the color of the second outer glass layer 12 and the color of the plurality of third inner glass layers 15a, 15b may be made different from each other.

In the glass laminate 10A prepared in step (d), the thickness of the plurality of third inner glass layers 15a, 15b may be the same as or different from the thickness of the first outer glass layer 11, the thickness of the second outer glass layer 12, the thickness of the first inner glass layer 13, and the thickness of the second inner glass layer 14. The thickness of the plurality of third inner glass layers 15a, 15b is, for example, 0.035 mm or more and 0.7 mm or less, preferably 0.05 mm or more and 0.5 mm or less, and more preferably 0.1 mm or more and 0.3 mm or less. [Step (e)]

Step (e) is a step of irradiating the glass laminate 10A with a laser light. In step (e), first, the first surface 10a of the glass laminate 10A is irradiated with a laser light. In step (e) in the present embodiment, as shown in (b) of FIG. 5, the laser irradiation apparatus 100 is used to irradiate the first surface 10a with the laser light L.

In step (e) in the present embodiment, by the irradiation of the first surface 10a with the laser light L as described above, a first hole H1A that penetrates the first outer glass layer 11, the first inner glass layer 13, and the third inner glass layer 15a from the first surface 10a toward the second surface 10b is formed in the glass laminate 10A, as shown in (c) of FIG. 5. The diameter of the first hole H1A is, for example, the same as the diameter of the first hole H1.

Subsequently, the formation of the first hole H1A by the irradiation with the laser light L described above is repeated. As a result, as shown in (d) of FIG. 5, a plurality of first holes H1A are formed in the glass laminate 10A. The pitch of the plurality of first holes H1 is, for example, the same as the pitch of the plurality of first holes H1. In the example shown in (d) of FIG. 5, three first holes H1 are formed in the glass laminate 10A.

Subsequently, the glass laminate 10A is turned upside down, and the second surface 10b of the glass laminate 10A is irradiated with a laser light. In step (e) in the present embodiment, as shown in (a) of FIG. 6, the laser irradiation apparatus 100 is used to irradiate the second surface 10b with the laser light L.

In step (e) in the present embodiment, by the irradiation of the second surface 10b with the laser light L as described above, a second hole H2A that penetrates the second outer glass layer 12, the second inner glass layer 14, and the third inner glass layer 15b from the second surface 10b toward the first surface 10a is formed in the glass laminate 10A. That is, in step (e) in the present embodiment, the second hole H2A is formed by irradiating the second surface 10b with the laser light L. The diameter of the second hole H2A formed by the irradiation of the second surface 10b with the laser light L is, for example, the same as the diameter of the first hole H1A.

The second hole H2A and the first hole H1A formed in step (e) communicate with each other, and thereby, a through-hole H penetrating from the first surface 10a toward the second surface 10b is formed. In step (e) in the present embodiment, a through-hole H is formed that penetrates the first outer glass layer 11, the first inner glass layer 13, the third inner glass layer 15a, the second inner glass layer 14, the third inner glass layer 15b, and the second outer glass layer 12 from the first surface 10a toward the second surface 10b.

Subsequently, the formation of the second hole H2A by the irradiation with the laser light L described above is repeated. As a result, as shown in (c) of FIG. 6, a plurality of second holes H2A are formed in the glass laminate 10A, and a plurality of through-holes H are formed. The pitch of the plurality of second holes H2A is, for example, the same as the pitch of the plurality of first holes H1A. That is, the pitch of the plurality of through-holes H in the present embodiment is, for example, the same as the pitch of the plurality of first holes H1A. In the example shown in (c) of FIG. 6, three through-holes H are formed in the glass laminate 10A.

[Step (f)]

Step (f) is a step of forming the first terminal 20, the second terminal 30, and the connection member 40 in the glass laminate 10A. Also in step (f) in the present embodiment, in the same manner as in step (c), as shown in (d) of FIG. 6, the first terminal 20 and the second terminal 30, which are electrically connected to each other by the connection member 40, are formed.

Through the above steps, the circuit board 1A shown in FIG. 4 is manufactured.

As described above, in the method for manufacturing the circuit board 1A, the light absorptance of the plurality of third inner glass layers 15a, 15b is lower than the light absorptance of the first outer glass layer 11 and the light absorptance of the second outer glass layer 12. In the method for manufacturing the circuit board 1A, by making the light absorptance of the plurality of third inner glass layers 15a, 15b lower than the light absorptance of the first outer glass layer 11 and the light absorptance of the second outer glass layer 12, it is possible to shorten the time required for the laser light L irradiation step while allowing the vaporized components generated by the laser light L to escape to the outside of the first hole H1A and the second hole H2A in both the process of forming the first hole H1A and the process of forming the second hole H2A. Therefore, the method for manufacturing the circuit board 1A can easily form the through-hole H for providing a connection member.

### Third Embodiment

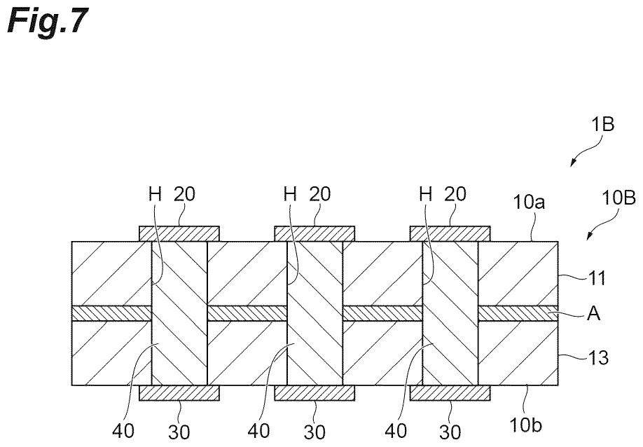

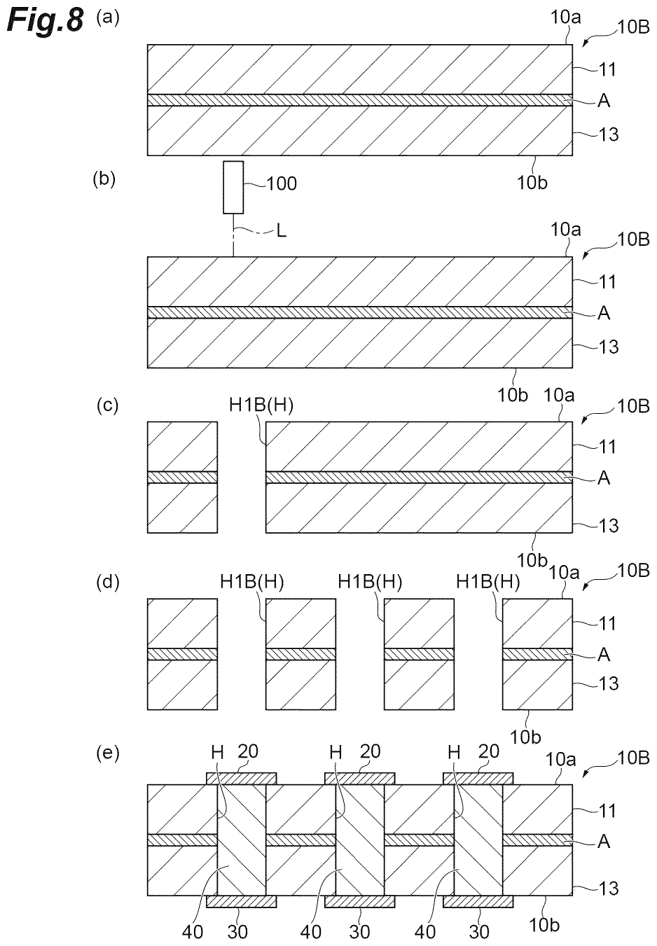

Next, a circuit board and a method for manufacturing the circuit board according to a third embodiment of the present disclosure will be described with reference to FIGS. 7 and 8. Hereinafter, points different from the first embodiment will be mainly described, and descriptions similar to or overlapping with the first embodiment may be omitted.

### (Configuration of Circuit Board)

First, the configuration of a circuit board 1B according to the third embodiment will be described with reference to FIG. 7. FIG. 7 is a diagram showing an example of a circuit board according to the third embodiment. As shown in FIG. 7, the circuit board 1B is, for example, a substrate serving as a core of a package substrate, and includes a glass laminate 10B, the first terminal 20, the second terminal 30, and the connection member 40. The glass laminate 10B, similarly to the glass laminate 10, includes the first surface 10a and the second surface 10b.

The glass laminate 10B is also configured by laminating a plurality of glass layers, similarly to the glass laminate 10, and in the present embodiment, is configured by laminating two glass layers. As shown in FIG. 7, the glass laminate 10B includes, as the two glass layers, the first outer glass layer 11 and the first inner glass layer 13. Also in the present embodiment, each of the first outer glass layer 11 and the first inner glass layer 13 is a glass plate.

In the glass laminate 10B, the first outer glass layer 11 and the first inner glass layer 13 constitute the outermost layers. Therefore, in the present embodiment, the first outer glass layer 11 includes the first surface 10a as its surface, and the first inner glass layer 13 includes the second surface 10b as its surface. In the glass laminate 10B, the first outer glass layer 11 and the first inner glass layer 13 are laminated in this order. Also in the present embodiment, each of the first outer glass layer 11 and the first inner glass layer 13 is bonded via the adhesive A.

Since the configuration of the first terminal 20, the second terminal 30, and the connection member 40 in the glass laminate 10B is the same as the configuration of the first terminal 20, the second terminal 30, and the connection member 40 in the glass laminate 10, a detailed description thereof is omitted.

### (Method for Manufacturing Circuit Board)

Next, a method for manufacturing the circuit board 1B will be described with reference to FIG. 8. FIG. 8 is a cross-sectional view for explaining the method for manufacturing the circuit board shown in FIG. 7.

The circuit board 1B can be manufactured, for example, through the following steps (g) to (i). That is, the method for manufacturing the circuit board 1B includes the following steps (g) to (i).
g) A step of preparing, as a substrate, a glass laminate including a first surface and a second surface, in which a plurality of glass layers are laminated, wherein the plurality of glass layers include a first outer glass layer including the first surface, and a first inner glass layer including the second surface.
h) A step of irradiating the glass laminate with a laser light.
i) A step of forming a connection member, a first terminal, and a second terminal.

Further, the step h) of irradiating the glass laminate with a laser light includes the following steps.
h1) A step of forming a first hole that penetrates the first outer glass layer and the first inner glass layer from the first surface toward the second surface by irradiating the first surface with a laser light.
h2) A step of repeating the above h1).
   [Step (g)]

Step (g) is a step of preparing the glass laminate 10B. In step (g) in the present embodiment, the glass laminate 10B including the first surface 10a and the second surface 10b, in which a plurality of glass layers are laminated, is prepared. The glass laminate 10B is, for example, a glass substrate. In this case, the glass laminate 10B may be a glass substrate having a thickness of, for example, 0.05 mm or more and 1.65 mm or less.

As shown in (a) of FIG. 8, the glass laminate 10B prepared in step (g) of the present embodiment includes, as the plurality of glass layers, the first outer glass layer 11 and the first inner glass layer 13. Since the material and the like of each glass layer in the glass laminate 10B are the same as the material and the like of each glass layer in the glass laminate 10, a detailed description thereof is omitted.

In the glass laminate 10B, the first outer glass layer 11 and the first inner glass layer 13 constitute the outermost layers. Therefore, in the glass laminate 10B prepared in step (g), the first outer glass layer 11 includes the first surface 10a as its surface, and the first inner glass layer 13 includes the second surface 10b as its surface. As described above, the first inner glass layer 13 is bonded to the first outer glass layer 11 on a side opposite to the first surface 10a. Therefore, in the glass laminate 10B prepared in step (g), the first outer glass layer 11 and the first inner glass layer 13 are laminated in this order.

[Step (h)]

Step (h) is a step of irradiating the glass laminate 10B with a laser light. In step (h), first, the first surface 10a of the glass laminate 10B is irradiated with a laser light. In step (h) in the present embodiment, as shown in (b) of FIG. 8, the laser irradiation apparatus 100 is used to irradiate the first surface 10a of the glass laminate 10B with the laser light L.

In step (h) in the present embodiment, by the irradiation of the first surface 10a with the laser light L as described above, a first hole H1B that penetrates the first outer glass layer 11 and the first inner glass layer 13 from the first surface 10a toward the second surface 10b is formed in the glass laminate 10B, as shown in (c) of FIG. 8. The diameter of the first hole H1B is, for example, the same as the diameter of the first hole H1. As described above, in the present embodiment, the glass laminate 10B includes, as the two glass layers, the first outer glass layer 11 and the first inner glass layer 13. Therefore, in step (h) in the present embodiment, the first hole H1B becomes the through-hole H that penetrates from the first surface 10a toward the second surface 10b. That is, in step (h) in the present embodiment, it can also be said that the through-hole H is formed by irradiating the glass laminate 10B with a laser light.

Subsequently, the formation of the first hole H1B (through-hole H) by the irradiation with the laser light L described above is repeated. As a result, as shown in (d) of FIG. 8, a plurality of first holes H1B are formed as through-holes H in the glass laminate 10B. The pitch of the plurality of first holes H1B is, for example, the same as the pitch of the plurality of first holes H1. In the example shown in (d) of FIG. 8, three first holes H1B (through-holes H) are formed in the glass laminate 10B.

[Step (i)]

Step (i) is a step of forming the first terminal 20, the second terminal 30, and the connection member 40 in the glass laminate 10B. Also in step (i) in the present embodiment, in the same manner as in step (c), as shown in (e) of FIG. 8, the first terminal 20 and the second terminal 30, which are electrically connected to each other by the connection member 40, are formed.

Through the above steps, the circuit board 1B shown in FIG. 7 is formed.

As described above, also in the method for manufacturing the circuit board 1B, the light absorptance of the first inner glass layer 13 is lower than the light absorptance of the first outer glass layer 11. Therefore, even in a glass laminate having a two-layer structure like the glass laminate 10B, it is possible to shorten the time required for the laser light L irradiation step while allowing the vaporized component to escape to the outside of the first hole H1B while removing the first inner glass layer 13 by the laser light L in the process of forming the first hole H1B (through-hole H). Therefore, according to the method for manufacturing the circuit board 1B, a hole for providing the connection member 40 can be easily formed.

Reference Signs List

1, 1A, 1B . . . circuit board, 10, 10A, 10B . . . glass laminate,
10a . . . first surface, 10b . . . second surface, 11 . . . first
outer glass layer, 12 . . . second outer glass layer, 13 . . .
first inner glass layer, 14 . . . second inner glass layer, 15a,
15b . . . third inner glass layer, 20 . . . first terminal, 30 . . .
second terminal, A . . . adhesive, H . . . through-hole, H1,
H1A, H1B . . . first hole, H2, H2A . . . second hole, L . . .
laser light.

1. A method for manufacturing a circuit board, the circuit board comprising: a substrate including a first surface and a second surface located on a side opposite to the first surface; a first terminal formed on the first surface; and a second terminal formed on the second surface and electrically connected to the first terminal,
the method comprising:
preparing a glass laminate as the substrate,
wherein the glass laminate, in which a plurality of glass layers are laminated, includes the first surface and the second surface; and
irradiating the glass laminate with a laser light,
wherein, in the preparing, the glass laminate is prepared in which the plurality of glass layers include a first outer glass layer including the first surface, and a first inner glass layer bonded to the first outer glass layer on a side opposite to the first surface,
wherein, in the irradiating, a first hole is formed that penetrates at least the first outer glass layer and the first inner glass layer from the first surface toward the second surface by irradiating the first surface with the laser light, and
wherein, a light absorptance of the first inner glass layer is lower than a light absorptance of the first outer glass layer.

2. The method for manufacturing a circuit board according to claim 1,
wherein, in the preparing, the glass laminate is prepared in which the first inner glass layer includes the second surface, and
wherein, in the irradiating, the first hole is formed that penetrates from the first surface to the second surface.

3. The method for manufacturing a circuit board according to claim 1,
wherein, in the preparing, the glass laminate is prepared in which the plurality of glass layers further include a second outer glass layer including the second surface, and
wherein, in the irradiating, a second hole is further formed that penetrates at least the second outer glass layer from the second surface toward the first surface and communicates with the first hole.

4. The method for manufacturing a circuit board according to claim 3,
wherein, in the preparing, the glass laminate is prepared in which the plurality of glass layers further include a second inner glass layer bonded to the second outer glass layer on a side opposite to the second surface,
wherein, in the irradiating, the second hole is formed that penetrates the second outer glass layer and the second inner glass layer by irradiating the second surface with the laser light, and
a light absorptance of the second inner glass layer is lower than the light absorptance of the second outer glass layer.

5. The method for manufacturing a circuit board according to claim 4, wherein the light absorptance of the second inner glass layer is lower than the light absorptance of the first outer glass layer.

6. The method for manufacturing a circuit board according to claim 4,
wherein, in the preparing, the glass laminate is prepared which further includes a plurality of third inner glass layers located between the first inner glass layer and the second inner glass layer,
wherein, in the irradiating,
the first hole is formed that penetrates the first outer glass layer, the first inner glass layer, and at least one third inner glass layer of the plurality of third inner glass layers, and
the second hole is formed that penetrates the second outer glass layer, the second inner glass layer, and a remaining third inner glass layer of the plurality of third inner glass layers, and
wherein, a light absorptance of the plurality of third inner glass layers is lower than the light absorptance of the first outer glass layer and the light absorptance of the second outer glass layer.

7. The method for manufacturing a circuit board according to claim 1, wherein each of the plurality of glass layers is a glass plate.

8. The method for manufacturing a circuit board according to claim 1, wherein each of the plurality of glass layers is bonded via an adhesive.

9. A circuit board comprising: a glass laminate including a first surface and a second surface located on a side opposite to the first surface, in which a plurality of glass layers are laminated; a first terminal formed on the first surface; and a second terminal formed on the second surface and electrically connected to the first terminal,
wherein the plurality of glass layers include:
a first outer glass layer including the first surface; and
a first inner glass layer bonded to the first outer glass layer on a side opposite to the first surface,
wherein, a through-hole penetrating from the first surface toward the second surface is formed in the glass laminate, and
wherein, a light absorptance of the first inner glass layer is lower than a light absorptance of the first outer glass layer.

10. The circuit board according to claim 9, wherein the first inner glass layer includes the second surface.

11. The circuit board according to claim 9,
wherein, the plurality of glass layers further include a second outer glass layer including the second surface, and
wherein, the light absorptance of the first inner glass layer is lower than a light absorptance of the second outer glass layer.

12. The circuit board according to claim 11,
wherein, the plurality of glass layers further include a second inner glass layer bonded to the second outer glass layer on a side opposite to the second surface, and
wherein, a light absorptance of the second inner glass layer is lower than the light absorptance of the second outer glass layer.

13. The circuit board according to claim 12, wherein the light absorptance of the second inner glass layer is lower than the light absorptance of the first outer glass layer.

14. The circuit board according to claim 12,
wherein, the plurality of glass layers further include a plurality of third inner glass layers located between the first inner glass layer and the second inner glass layer, and
wherein, a light absorptance of the plurality of third inner glass layers is lower than the light absorptance of the first outer glass layer and the light absorptance of the second outer glass layer.

15. The circuit board according to claim 9, wherein each of the plurality of glass layers is a glass plate.

16. The circuit board according to claim 9, wherein each of the plurality of glass layers is bonded via an adhesive.
